(19) United States
(12) Patent Application Publication
(10) Pub. No.: US 2009/0205715 A1
(43) Pub. Date: Aug. 20, 2009

(54) Chalcopyrite Solar Cell and Manufacturing Method Thereof

(75) Inventors: Satoshi Yonezawa, Tochigi (JP); Tadashi Hayashida, Tochigi (JP)

Correspondence Address: ARENT FOX LLP, 1050 CONNECTICUT AVENUE, N.W., SUITE 400, WASHINGTON, DC, 20036, US

(73) Assignee: HONDA MOTOR CO., LTD., Minato-ku, Tokyo (JP)

(21) Appl. No.: 11/884,485

(22) PCT Filed: Feb. 1, 2006
(86) PCT No.: PCT/JP2006/301664

§ 371 Date: Aug. 16, 2007

(30) Foreign Application Priority Data
Feb. 16, 2005 (JP) 2005-038955

(51) Int. Cl. H01L 31/0264; H01L 31/18

(52) U.S. Cl. 136/265; 438/95; 257/E31.004

(57) ABSTRACT

A solar cell having high conversion efficiency and excellent flexibility is realized. A mica substrate or laminated mica substrate is used as substrate 1. The mica and laminated mica have high insulating property and heat resistance temperature, which can be selenized at an appropriate treatment temperature through vapor-phase selenization process, high conversion efficiency and excellent flexibility resultantly suitable for mass-production can be obtained. On the other hand, because the surfaces of the mica and laminated mica have large surface roughnesses, it is impossible to induce leakage to obtain high conversion efficiency in the case where a chalcopyrite based light absorbing layer 6 is simply formed. In the present invention, an intermediate layer 2 of ceramic based material and binder layer 4 are interposed between the mica substrate 1 and a molybdenum electrode 5. By providing the intermediate layer 2 and binder layer 4, surface coating property is enhanced and a solar cell having high conversion efficiency can be realized.

### TECHNICAL FIELD

The present invention relates to a solar cell including a light absorbing layer of chalcopyrite compound, and more particularly to a solar cell having high flexibility, suitable for mass-production, and having high conversion efficiency, and a manufacturing method thereof.

### BACKGROUND ART

Solar cells adapted for receiving rays of light to convert them into an electric energy are classified into solar cells of the bulk system and solar cells of the thin film system depending upon thickness of the semiconductor. Among them, the solar cell of the thin film system is a solar cell in which the semiconductor layer has a thickness lower than several 10 μm to several μm, and is classified into solar cell of the Si thin film system and solar cell of compound thin film system. As the solar cell of the compound thin film system, there are solar cells of the II-VI group compound and solar cells of the chalcopyrite compound, etc. Until now, several solar cells of compound thin film system have been manufactured. Among them, solar cells of the chalcopyrite compound are called CIGS (Cu(InGa)Se) system thin film solar cell, CIGS solar cell, or solar cell of the I-III-VI group system as another name due to the substances used.

The chalcopyrite based solar cells are solar cells formed such that chalcopyrite compound is used as light absorbing layer, and have features such as high efficiency, no light deterioration (change with lapse), excellent radiation proof characteristic, broad light absorbing wavelength region and high light absorbing efficient, etc. At present, studies aiming at mass-production are being performed.

The cross sectional structure of a typical chalcopyrite solar cell is shown in FIG. 1. As shown in FIG. 1, the chalcopyrite solar cell includes a lower part electrode thin film formed on a glass substrate, a light absorbing layer thin film containing copper, indium, gallium and selenium, a buffer layer thin film formed on the upper side of the light absorbing layer thin film, and an upper part electrode thin film. When rays of light such as sun beams, etc. are irradiated onto the chalcopyrite based solar cell, pairs of electron (−) and hole (+) are generated. At junction surface between the p-type semiconductor and the n-type semiconductor, electrons (−) are concentrated on the n-type semiconductor and holes (+) are concentrated on the p-type semiconductor. As a result, an electromotive force is produced between the n-type semiconductor and the p-type semiconductor. By connecting lead wires to the electrodes in this state, it is possible to take out a current toward the outside.

Process steps for manufacturing chalcopyrite solar cell are shown in FIGS. 2 and 3. First, a Mo (molybdenum) electrode serving as a lower part electrode is formed as film on a glass substrate such as soda lime glass, etc. by sputtering. Next, as shown in FIG. 3(a), the Mo electrode is divided by laser irradiation, etc. (first scribing process). After the first scribing process, shavings are rinsed with water and the like to attach copper (Cu), indium (In) and gallium (Ga) by sputtering, etc. to form a precursor. By throwing this precursor into a furnace to anneal the precursor under the atmosphere of H₂Se gas so that a light absorbing layer thin film is formed. This annealing process is ordinarily called vapor-phase selenization process or simply selenization process.

Next, an n-type buffer layer such as CdS, ZnO or InS, etc. is laminated on the light absorbing layer. The buffer layer is formed by process such as sputtering or CBD (Chemical Bath Deposition), etc. as a typical process. Next, as shown in FIG. 3(b), the buffer layer and the precursor are divided by laser irradiation or metallic needle, etc. (second scribing process).

Thereafter, as shown in FIG. 3(c), a transparent electrode (TCO) such as ZnOAl, etc. serving as the upper part electrode is formed by sputtering. Finally, as shown in FIG. 3(d), the TCO, the buffer layer and the precursor are divided by laser irradiation or metallic needle, etc. (third scribing process) so that the CIGS based thin film solar cell is completed.

The solar cell obtained here is called cell, and plural cells are packaged in actual use to process the packaged cell as module (panel). The packaged cell body is divided into solar cells forming plural serial stages by respective scribing processes. By changing the number of serial stages, it becomes possible to arbitrarily perform design change of cell voltage.

In such conventional chalcopyrite solar cell, glass substrate has been used as substrate material thereof. This is because the glass substrate has insulating property, obtainment thereof is easy, cost thereof is relatively low, adhesion thereof with respect to Mo electrode layer (lower part electrode thin film) is high, and the surface thereof is smooth. Further, it is also mentioned that sodium component included in glass is diffused in the light absorbing layer (p-layer) so that the energy conversion efficiency becomes high. To the contrary, since the glass has low melting point so that annealing temperature cannot be set to a high temperature in the selenization process, there were drawbacks that the energy conversion efficiency is resultantly held down to a lower value, the substrate becomes thick and the mass becomes large so that the manufacturing facility or equipment becomes large, and handling after manufacturing is also inconvenient, and deformation hardly takes place so that mass-production process such as roll-to-roll process, etc. cannot be applied.

To solve these problems, chalcopyrite based solar cell using polymer film substrate is proposed (see e.g., Patent Document 1). Moreover, there is also proposed a technology in which base where layers of silicon oxide or iron fluoride are respectively formed on the upper side surface and the lower side surface of a stainless steel substrate is used to form chalcopyrite solar cell structure thereon (see e.g. Patent Document 2). Further, there is also disclosed a technology in which glass, alumina, mica, polyimide, molybdenum, tungsten, nickel, graphite and stainless steel are enumerated as chalcopyrite based substrate material (see, e.g., Patent Document 3).

Patent Document 1: Japanese Patent Laid-Open No. 5-259494

Patent Document 2: Japanese Patent Laid-Open No. 2001-339081

Patent Document 3: Japanese Patent Laid-Open No. 2000-58893

### DISCLOSURE OF THE INVENTION

Among solar cells using material except for glass as substrate material of the chalcopyrite solar cell of the related art, in connection with solar cells using polymer film described in the Patent Document 1, it was impossible to perform treatment at a high temperature of 260° C. or more in the case of, e.g., polyimide from a viewpoint of characteristic. Accordingly, high temperature process above 500° C. like vapor-phase selenization cannot be used. As a result, it was impossible to manufacture solar cells having high conversion efficiency.

Moreover, in the technology in which layers (protective layers) of silicon oxide or iron fluoride are respectively formed on upper and lower surfaces of a stainless steel substrate, which is described in the Patent Document 2, it is insufficient to protect the stainless steel substrate from aggressiveness of H₂Se gas in the vapor-phase selenization process. As a result, there was the inconvenience that Mo electrode layer (backside electrode thin film) is peeled from corroded stainless steel substrate, etc. Further, since the protective layer is separated so that the conductive stainless steel substrate is exposed, it was impossible to introduce scribing process using metallic needle.

Further, in the technology described in the Patent Document 3, various substrate materials are enumerated. However, the technologies described as completed examples of the embodiments thereof are all directed to technologies using glass substrate. No disclosure is made in detail to such an extent that those persons skilled in the art can carry out with respect to respective represented substrate materials. For examples, the substrate is annealed within the range from 385° C. to 495° C., but the reason why such implementation is employed is that temperature setting is made in correspondence to soda lime glass, so whether or not the substrate can be prepared in the same process by using other recited substrate materials is not clear.

As stated above, in the related arts, in actual circumstances, there is not used a substrate material satisfying high insulating property, easy obtainment, relatively low cost, satisfactory adhesion with respect to Mo electrode layer (lower part electrode thin film), smooth surface, melting point of 600° C. or more, light weight and good flexibility.

An object of the present invention is to provide a solar cell which satisfies the above-described requirements for substrate material so that high conversion efficiency can be obtained.

Another object of the present invention is to provide a solar cell having excellent flexibility, adapted to mass-production process of roll-to-roll process, and available high conversion efficiency.

A solar cell according to the present invention includes:

a substrate of mica or material containing mica;

an intermediate layer for smoothing or planarizing a surface of the substrate, which is formed on the substrate;

a binder layer formed on the intermediate layer;

a metallic lower part electrode layer formed on the binder layer;

a p-type light absorbing layer formed on the metallic lower part electrode layer, and made of chalcopyrite based material;

an n-type buffer layer formed on the light absorbing layer; and

an n-type transparent electrode layer formed on the buffer layer.

In the present invention, substrate of mica or material containing mica as main component is used as the substrate. The mica has the characteristic in which insulating property exhibits high value of 10¹² to 10¹⁶Ω, heat resistance temperature takes high value of 800 to 1000° C., and tolerance to acid or alkali and H₂Se gas is also high. Accordingly, since the vapor-phase selenization process can be performed at a suitable temperature, it is possible to obtain high conversion efficiency. Namely, in the manufacturing process for CIGS solar cell, in the case where selenization process is performed at a relatively low treatment temperature of the order of 500° C. used in the soda lime glass substrate, Ga is segregated in uncrystallized state on the lower electrode thin film side of the light absorbing layer. For this reason, the bandgap is small so that current density would be lowered. To the contrary, when heat treatment of vapor-phase selenization process is performed at a temperature within the range from 600° C. to 700° C., Ga is uniformly diffused in the light absorbing layer. In addition, since the uncrystallized state is eliminated, the bandgap is extended so that an open-circuit voltage (Voc) is resultantly improved. Accordingly, mica or material containing mica as major component is used as substrate material, thereby making it possible to realize a solar cell having high conversion efficiency. Further, since the mica and the laminated mica have high flexibility, production can be made by the roll-to-roll manufacturing process. For this reason, it is possible to adapt to mass-production requirement.

However, it has been found that the surface of the mica substrate or laminated mica substrate of material containing mica as main component is not smooth, and the maximum surface roughness of 5 to 6 μm exists within the range of several 10 μm. When a substrate having such a large surface roughness is used, the surface coating property becomes imperfect. Thus, there is a tendency in which leakage is induced so that an open-circuit voltage (Voc) of the solar cell is lowered. As a result, it would take place that sufficient conversion efficiency cannot be provided. In order to solve this problem, in the present invention, an intermediate layer having thick film for planarizing or smoothing the substrate surface is formed between a mica substrate or a laminated mica substrate and a metallic electrode. By forming such an intermediate layer, it is possible to ensure matching between various layers constituting solar cell formed on the substrate, and it is possible to eliminate an inconvenience such that conversion efficiency is lowered. From a viewpoint of planarizing the surface of mica or laminated mica, it is desirable that the thickness of the intermediate layer to be formed is 2 μm or more. From a viewpoint of ensuring the flexibility of the substrate, it is desirable that the thickness of the intermediate layer to be formed is 20 μm or less. On the other hand, in the case of forming an intermediate layer of a thick film, when oxide film or nitride film is formed by vacuum treatment such as sputtering, etc., there would take place inconveniences such that not only it takes long time in film formation, but also crack takes place when the solar cell is bent or curved and flexibility is also lowered. In view of the above, in the present invention, the intermediate layer of thick film is formed by non-vacuum treatment, e.g., coating using brush, spray coating, silk-print or spin-coating, etc. By utilizing such film formation technology based on non-vacuum treatment, it is possible to easily form an intermediate layer having a desired thickness.

Further, in the present invention, a binder layer of nitride based compound is provided between the intermediate layer formed on mica substrate or laminated mica substrate and molybdenum electrode formed on the upper side of the intermediate layer. Since the binder layer of nitride such as TiN and TaN, etc. has the barrier effect for suppressing diffusion of impurity, and high adhesion between the binder layer and molybdenum, etc., impurities or constituent materials included in the substrate and the intermediate layer are prevented from being diffused into the light absorbing layer of the chalcopyrite based material, and high adhesion can be ensured between the intermediate layer and the metallic electrode layer.

In the preferred example of a solar cell according to the present invention, the substrate is constituted by laminated mica including powder of mica and resin which are mixed, and fabricated through rolling process and baking process. Since resin is mixed in the laminated mica, the laminated mica has heat resistance lower than that of the pure mica substrate, but has heat resistance temperature of 600 to 800° C. Accordingly, it is possible to perform treatment at temperature of 600 to 700° C. which is the optimum temperature of the vapor-phase selenization treatment. Further, since the solar cell has high flexibility, it is suitable for roll-to-roll process. In addition, cost is very low as compared to the glass substrate. Accordingly, since the laminated mica is used as the substrate, it is possible to manufacture, at a lower manufacturing cost, a solar cell adapted to mass-production and having high conversion efficiency.

In the preferred example of the solar cell according to the present invention, the intermediate layer is constituted by ceramic based material, and its thickness is set to thickness of 2 to 20 μm. Since the ceramic based material has high heat resistance temperature, the vapor-phase selenization process can be performed at a suitable temperature. Accordingly, it is possible to realize a solar cell having high conversion efficiency.

In another preferred example of the solar cell according to the present invention, the binder layer is constituted by nitride based compound including TiN or TaN, and its thickness is set to thickness within the range from 3000 Å to 1 μm.

In a further preferred example of the solar cell according to the present invention, a surface smoothing layer constituted by silicon nitride or silicon oxide is formed between the intermediate layer and the binder layer.

A method of manufacturing a solar cell according to the present invention including, in manufacturing a solar cell including a light absorbing layer made of chalcopyrite based material,

preparing a substrate of mica or material containing mica to form an intermediate layer for planarizing a surface of the substrate on the substrate,

forming a binder layer on the intermediate layer,

forming a metallic lower part electrode layer on the binder layer,

forming the light absorbing layer of the chalcopyrite compound on the metallic lower part electrode layer, and

forming a transparent electrode layer on an upper side of the light absorbing layer.

In the solar cell manufacturing method according to the present invention, since the substrate, the intermediate layer and the intermediate buffer layer formed on the substrate are constituted by material having high heat resistance temperature, treatment can be performed at an optimum treatment temperature in performing vapor-phase selenization process with respect to precursor of chalcopyrite compound. As a result, it is possible to manufacture a solar cell having high conversion efficiency.

In preferred example of the solar cell manufacturing method according to the present invention, the forming of the light absorbing layer includes: forming a precursor on a base where the metallic electrode layer is formed; and performing vapor-phase selenization process with respect to precursor at a treatment temperature of 600 to 700° C.

The mica substrate or the laminated mica substrate coated by ceramic based material according to the present invention is used, thereby making it possible to manufacture a chalcopyrite solar cell which is light in weight, and has high flexibility and high conversion efficiency. Particularly, the laminated mica substrate smoothed by ceramic based material is used, thereby making it possible to manufacture a chalcopyrite based solar cell which is inexpensive and has high conversion efficiency as compared to the case where the glass substrate is used. Moreover, binder layer for preventing impurity from the mica substrate from being diffused into the light absorbing layer (having the effect to enhance adhesion in combination), thereby making it possible to prevent diffusion of impurity from the substrate side.

Further, the silicon based smoothing layer of SiN or SiO₂ is provided, thereby making it possible to smooth micro roughness of the mica substrate coated by ceramic based material to improve adhesion with respect to the binder layer.

### BRIEF DESCRIPTION OF THE DRAWINGS

FIG. 1 is a cross sectional view showing the structure of a conventional chalcopyrite solar cell;

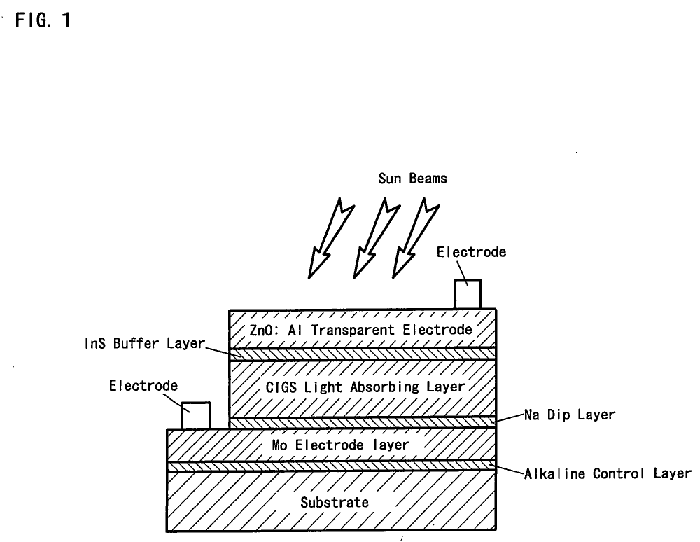

FIG. 2 is a view showing a series of manufacturing process steps of the conventional chalcopyrite solar cell;

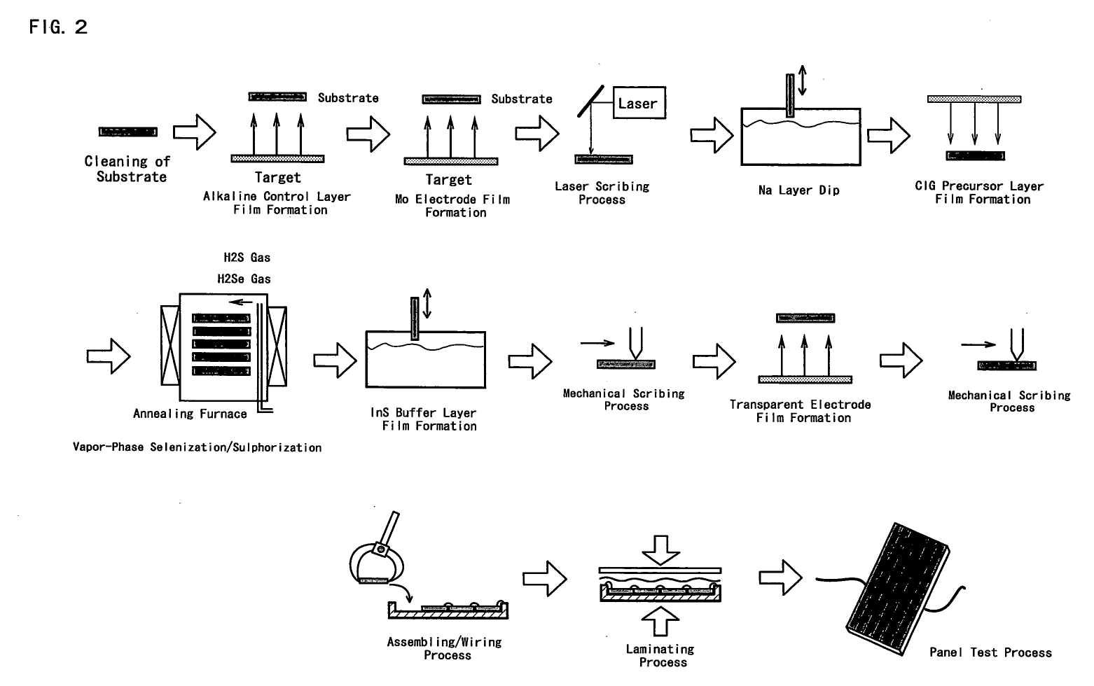

FIG. 3 is a view for explaining the essential part of the manufacturing process steps;

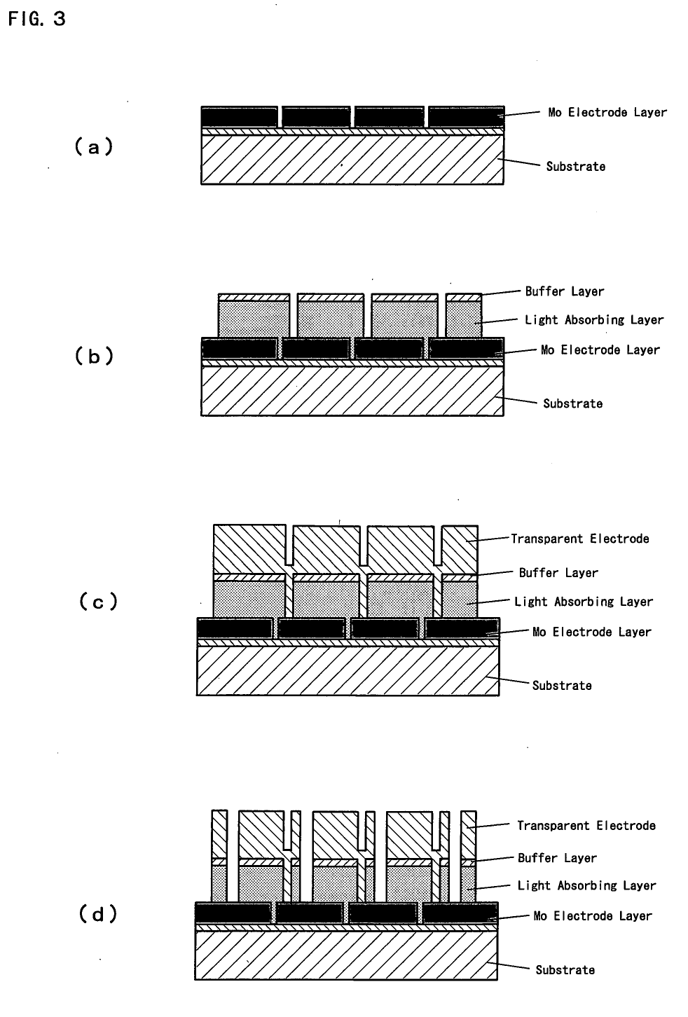

FIG. 4 is a graph showing surface shape of laminated mica substrate;

FIGS. 5(A) and 5(B) are diagrams showing surface shape after intermediate layer of thick film is formed on the laminated mica substrate surface;

FIG. 6 is a cross sectional view showing the configuration of an example of a solar cell according to the present invention;

FIGS. 7(A) and 7(B) are views for explaining the performances of the solar cell according to the present invention; and

FIGS. 8(A) and 8(B) are graphs showing the results by the Auger analysis indicating impurities included in respective layers of the solar cell.

### BEST MODE FOR CARRYING OUT THE INVENTION

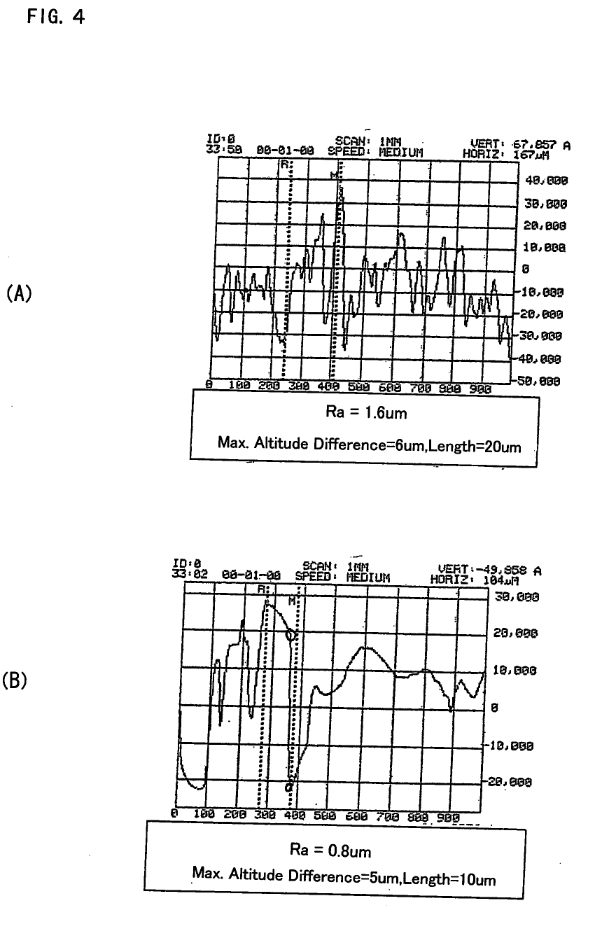

Prior to explanation of an example, the surface shape of a laminated mica substrate will be explained. FIGS. 4(A) and 4(B) indicate measurement results of surface shapes at arbitrary two parts of the laminated mica substrate. In FIG. 4, the abscissa indicates position in a lateral direction of the laminated mica substrate, and the ordinate indicates position in a height direction. As the feature of the laminated mica substrate, the maximum altitude difference is extremely sharply changed (the aspect ratio is large). As seen from FIG. 4, the maximum altitude difference of 5 to 6 μm exists within the range of several 10 μm in a lateral direction. It is understood that this cause results from the process for laminated mica. It is understood that since crushed mica is mixed in resin, crushed mica pieces exist on the surface so that the aspect ratio is extremely increased. In this case, surface roughnesses of the laminated mica substrate with respect to measured two parts were expressed as Ra=1.6 μm and 0.8 μm, respectively. In the case of such a surface state, electrode of Mo, etc. is directly formed as film on the substrate. Even if the light absorbing layer is formed thereon, the surface coating property becomes imperfect. As a result, leakage is induced so that the function as the solar cell is remarkably lowered. In concrete terms, open-circuit voltage (Voc) of the solar cell is lowered so that the conversion efficiency is lowered.

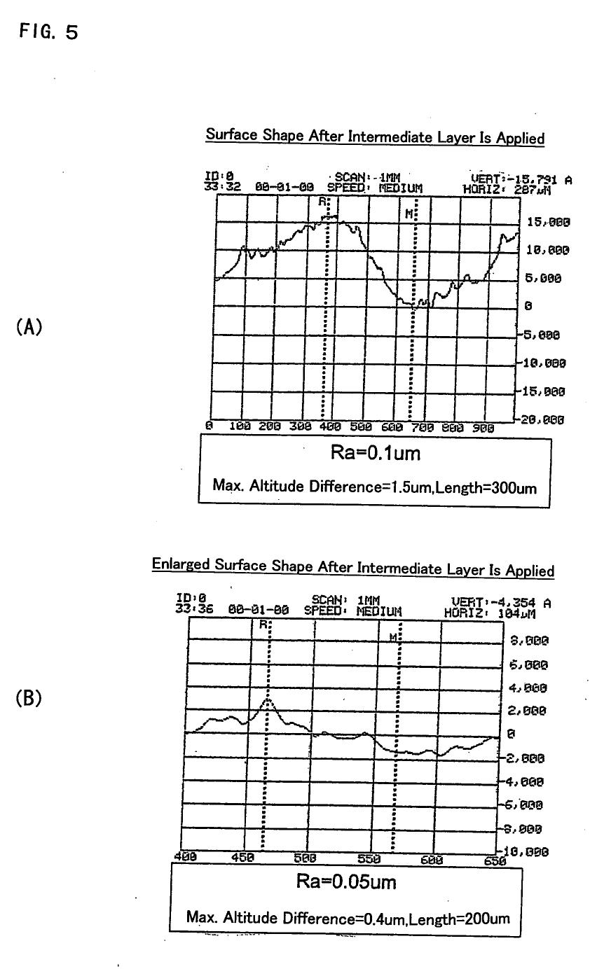

Next, measurement results of surface shapes after ceramic based paint serving as material of the intermediate layer is coated on the laminated mica substrate surface so that its thickness becomes equal to 8 μm are shown in FIGS. 4A and 4B. FIG. 5 shows measurement results of arbitrary two parts. As apparent from FIG. 5, large undulation that the substrate primarily has was measured. However, the maximum altitude difference of 5 to 6 μm taking place within the range of several μm which has been observed by the surface shape measurement of the laminated mica substrate is lost. Accordingly, it is desirable from the measurement results of FIGS. 4 and 5 that the thickness of the intermediate layer is 2 μm or more, and is preferably 5 μm.

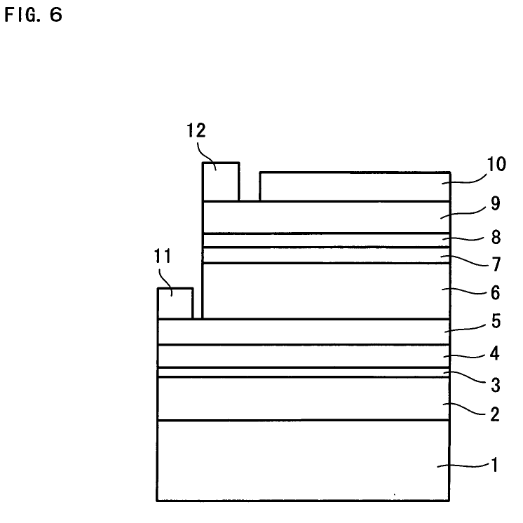

FIG. 6 is a cross sectional view showing the configuration of an example of a solar cell according to the present invention. In this example, a laminated mica substrate 1 is used as substrate. The laminated mica is high insulating material manufactured by mixing mica in powder form with resin and undergoing rolling process and baking process. The heat resistance temperature of the laminated mica is approximately 600 to 800° C. This laminated mica can tolerate high temperature higher than heat resistance temperature (500 to 550° C.) of soda lime glass used in the conventional solar cell. Moreover, since an optimum treatment temperature in the vapor-phase selenization process is 600 to 700° C., a light absorbing layer of chalcopyrite can be also formed at an optimum temperature. In addition, since the laminated mica has high flexibility, it is preferable also in the case where production is made by roll-to-roll process.

An intermediate layer 2 of thick film is formed on the laminated mica substrate 1. This intermediate layer 2 serves to planarize or smooth the laminated mica substrate surface, and is formed so that its thickness becomes equal to 2 to 20 μm. This intermediate layer 2 can be constituted by ceramic based material. As an example, there may be used a paint including titanium of 39 wt %, oxygen of 28.8 wt %, silicon of 25.7 wt %, carbon of 2.7 wt % and aluminum of 1.6 wt %. Moreover, as a method of forming the intermediate layer 2 of thick film, non-vacuum treatment is used to form painted film by, e.g., coating using brush, spray coating, silk-print or spin-coating, etc. so that the intermediate layer is formed via drying process and baking process. As the thickness of the intermediate layer, thickness of 2 μm or more is required in order to planarize the surface of the laminated mica. It is desirable that its thickness is 20 μm or less for ensuring flexibility when the solar cell is formed. In a ceramic based material used in formation of the intermediate layer, inorganic resin manufactured by sol-gel process is used as base, and silicon and oxygen are strongly bound by ionic bond. This paint has heat resistance temperature of about 1200° C. Accordingly, also in the ideal treatment temperature of the vapor-phase selenization process for forming chalcopyrite solar layer which will be described later, the intermediate layer has sufficient heat resistance characteristic.

A surface smoothing layer 3 is formed on the intermediate layer 2. As such surface smoothing layer 3, SiN or SiO₂ may be used. The surface smoothing layer 3 is formed by dry process such as sputtering, etc. The reason why Si based material is used is that there are mentioned the facts in which the surface of the intermediate layer 2 is permitted to be more smoothed surface, and adhesion between intermediate layer of the underlying ceramic based material and binder layer which will be described later can be enhanced. This surface smoothing layer 3 may be formed as occasion demands, and may be also omitted.

A binder layer 4 is formed on the surface smoothing layer 3. This binder layer 4 is formed for preventing diffusion of impurities or constituent materials from the underlying mica substrate and the intermediate layer, and for improving adhesion between a metallic electrode 5 such as molybdenum or tungsten, etc. formed thereon and mica substrate structure (including mica substrate 1 and intermediate layer 2). As material of the binder layer 4, nitride based compound such as TiN or TaN, etc. is suitable. It has been found, in accordance with the experimental result, that the thickness of the binder layer 4 is required to be 3000 Å or more for the purpose of ensuring barrier characteristic, and the thickness of 5000 Å to 1 μm is optimum for the purpose of performing compatibility between barrier characteristic and adhesion.

On the binder layer 4, there are formed respective layers similarly to the conventional chalcopyrite based solar cell. Namely, first, a molybdenum (Mo) electrode 5 serving as a lower part electrode is formed by sputtering to divide the Mo electrode 5 by laser irradiation (first scribing process).

Next, copper (Cu), indium (In) and gallium (Ga) are attached by sputtering, etc. to form a precursor thereafter to dispose this precursor within a furnace to form a chalcopyrite based light absorbing layer 6 by the vapor-phase selenization process for performing annealing process under the atmosphere of H₂Se gas. As occasion demands, prior to the vapor-phase selenization process, there may be performed a process to add sodium (Na) as alkaline metal. This is because grains of the light absorbing layer grow by diffusing Na into the light absorbing layer so that energy conversion efficiency is enhanced.

The light absorbing layer 6 is a p-type semiconductor layer. An n-type buffer layer 7 functioning as n-type semiconductor layer such as CdS, ZnO or InS, etc. is formed on the light absorbing layer by process such as sputtering or CBD (Chemical Bath Deposition), etc. so that its thickness becomes equal to several 100 Å. On the n-type buffer layer 7, as occasion demands, there may be formed a high resistance layer 8 so that its film thickness becomes equal to several 100 Å. Thereafter, the light absorbing layer and the buffer layer are divided by laser irradiation or metallic needle (second scribing process).

Thereafter, a transparent electrode (TCO) 9 such as ZnOAl, etc. serving as an upper part electrode is formed by sputtering or CBD, etc. to form a reflection preventing film 10 thereon. Further, the reflection preventing film, the transparent electrode, the binder layer and the light absorbing layer are divided by laser irradiation or metallic needle, etc. (third scribing process). Finally, take-out electrodes 11 and 12 are formed on the lower part electrode layer 5 and the upper part electrode layer 9. Thus, a chalcopyrite based thin film solar cell is completed.

It is to be noted that, in connection with process steps subsequent to the process step for forming molybdenum electrode 5, wet process such as CBD, etc. may be replaced by dry process to introduce “roll-to-roll process” for delivering a laminated mica substrate from roll to form a solar cell. In introducing roll-to-roll process, a process of forming an intermediate layer of ceramic based material may be implemented onto a laminated mica substrate in advance, or may be incorporated into the roll-to-roll process.

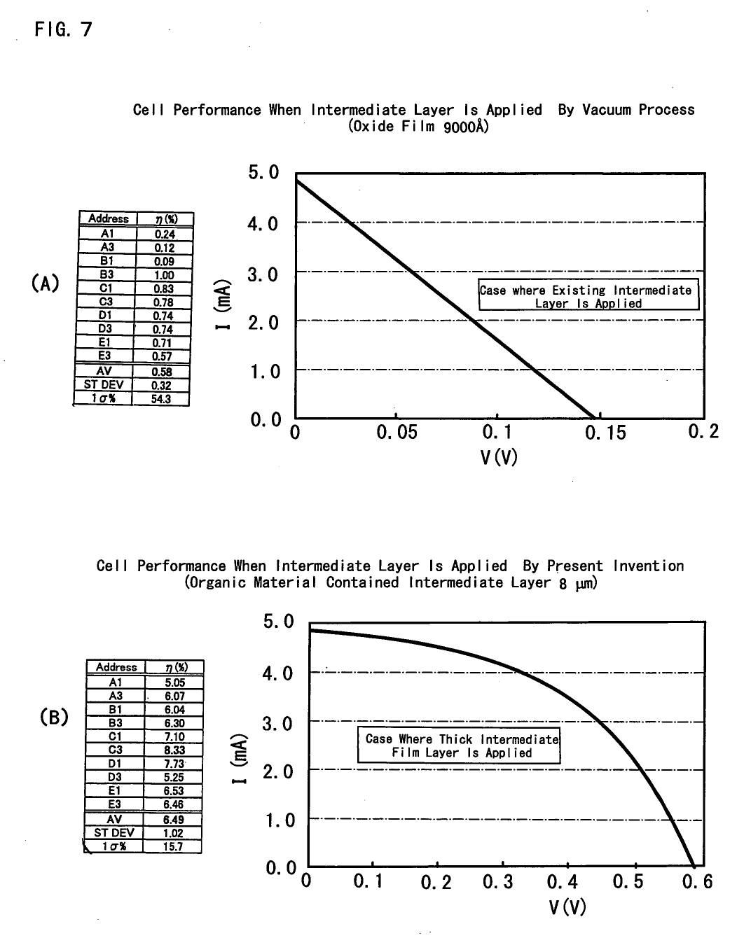

The performance of the solar cell prepared in accordance with the above-described example will now be explained. As a comparative example, there is used a solar cell in which an oxide film of 9000 Å as an intermediate layer and a binder layer also functioning as a barrier layer are formed on a laminated mica substrate, and a Mo electrode layer is formed thereon. FIG. 7(A) shows the performance of the solar cell according to the comparative example, and FIG. 7(B) shows the performance of the solar cell prepared by the present invention. In the solar cell of the comparative example in which no intermediate layer of thick film of ceramic based material is formed, average conversion efficiency of ten parts was expressed as η=0.58%, average open-circuit voltage was expressed as Voc=0.13V, the maximum conversion efficiency was expressed as η=1.0%, and maximum open-circuit voltage was expressed as Voc=0.15V. To the contrary, in the solar cell according to the present invention including intermediate layer of thick film of ceramic based material, average conversion efficiency of ten parts was expressed as η=6.5%, average open-circuit voltage was expressed as Voc=0.49V, the maximum conversion efficiency was expressed as η=8.3%, and the maximum open-circuit voltage was expressed as Voc=0.57V. Also with respect to fill factor (FF), improvement is greatly made in the case of the solar cell according to the present invention.

From this experimental result, it has been seen that in the case where oxide film or nitride film is formed by vacuum treatment such as sputtering, etc. on the laminated mica substrate to form Mo electrode layer thereon, it is impossible to improve the characteristic as a solar cell. On the other hand, in the case where an intermediate layer of thick film is formed by non-vacuum treatment on a laminated mica substrate to form a Mo electrode layer thereon, high conversion efficiency and large open-circuit voltage can be provided as a solar cell. This is because it is considered that coplanarity and smoothing characteristic of the surface of the laminated mica substrate cannot be improved even with treatment such as sputtering, etc., and leakage is induced to lower the performance of the solar cell.

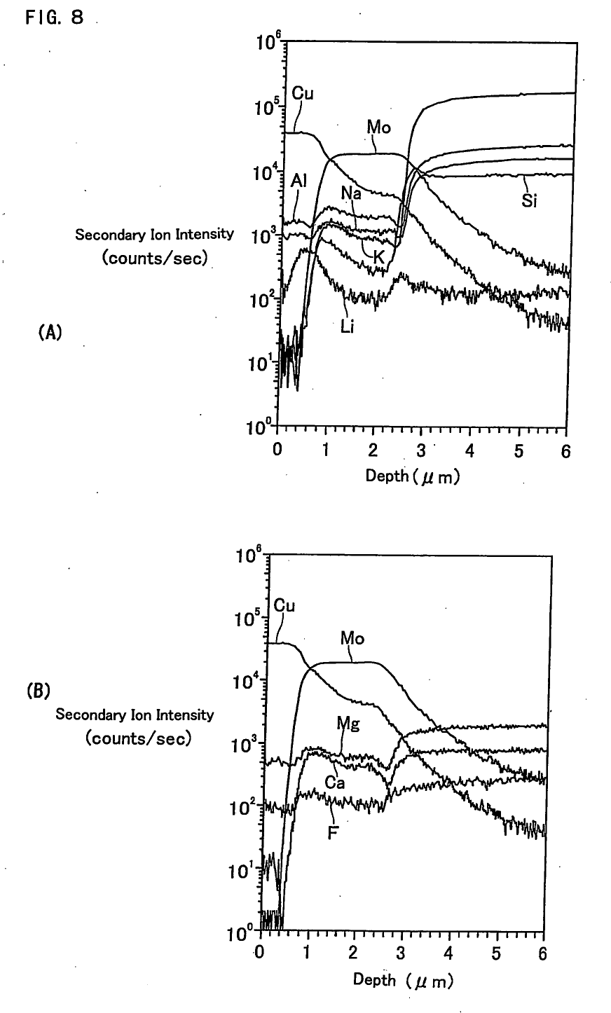

The effects of the binder layer will now be explained. There are prepared a solar cell in which Mo electrode is directly formed on a laminated mica substrate, and a solar cell in which a binder layer of TiN is formed on a laminated mica substrate to form a Mo electrode layer thereon. The measurement results obtained by measuring materials distributed in respective layers by the Auger method are shown in FIG. 8. In this case, in order to confirm the effects of the binder layer, no intermediate layer of ceramic based material is formed. FIG. 8(A) shows data of solar cell in which Mo layer is directly formed on the laminated mica substrate, and FIG. 8(B) shows data of solar cell including barrier layer. As shown in FIG. 8(A), in the solar cell in which no barrier layer exists, alkaline earth metallic elements such as Al, K, Li, Na, Mg or F, etc. included in the mica substrate are diffused. These materials are impurities for the chalcopyrite based light absorbing layer. In the case where they are diffused, such a solar cell cannot function as a solar cell. Accordingly, from a viewpoint of enhancing the function as a solar cell, the binder layer also functioning as barrier layer for preventing impurity diffusion is extremely important.

The present invention is not limited to the above described example, but may be variously changed or modified. For example, ceramic based material provided for planarizing or smoothing the surface of the mica substrate and the laminated mica substrate is taken an example. Various materials which can be treated within the temperature range from 600 to 700° C. may be used. Further, while n-type semiconductor layer is formed between the chalcopyrite based light absorbing layer and the transparent electrode in the above-described example, the transparent electrode itself is also permitted to function as n-type layer without forming such n-type semiconductor layer.

1. A chalcopyrite solar cell including:
a substrate of mica or material containing mica;
an intermediate layer for smoothing or planarizing a surface of the substrate, which is formed on the substrate;
a binder layer formed on the intermediate layer;
a metallic lower part electrode layer formed on the binder layer;
a p-type light absorbing layer formed on the metallic lower part layer, and made of chalcopyrite compound;
an n-type buffer layer formed on the light absorbing layer; and
an n-type transparent electrode layer formed on the buffer layer.

2. The chalcopyrite solar cell according to claim 1,
wherein the substrate is constituted by laminated mica obtained by mixing powder of mica and resin, and undergoing rolling process and baking process.

3. The chalcopyrite solar cell according to claim 1,
wherein the intermediate layer is constituted by coating film of ceramic-based material, and its thickness is set to a thickness within the range of 2 μm to 20 μm.

4. The chalcopyrite solar cell according to claim 1, wherein a surface smoothing layer constituted by silicon nitride or silicon oxide is formed between the intermediate layer and the binder layer.

5. A method of manufacturing a chalcopyrite solar cell, including:
preparing a substrate of mica or material containing mica to form an intermediate layer for planarizing a surface of the substrate on the substrate;
forming a binder layer on the intermediate layer;
forming a metallic lower part electrode layer on the binder layer;
forming a light absorbing layer of chalcopyrite compound on the metallic lower part electrode layer; and
forming a transparent electrode layer on the upper side of the light absorbing layer.

6. The chalcopyrite solar cell according to claim 2,
wherein the intermediate layer is constituted by coating film of ceramic-based material, and its thickness is set to a thickness within the range of 2 μm to 20 μm.

7. The chalcopyrite solar cell according to claim 2, wherein a surface smoothing layer constituted by silicon nitride or silicon oxide is formed between the intermediate layer and the binder layer.

8. The chalcopyrite solar cell according to claim 3, wherein a surface smoothing layer constituted by silicon nitride or silicon oxide is formed between the intermediate layer and the binder layer.

9. The chalcopyrite solar cell according to claim 6, wherein a surface smoothing layer constituted by silicon nitride or silicon oxide is formed between the intermediate layer and the binder layer.
